(19) United States
(12) Patent Application Publication
(10) Pub. No.: US 2006/0257751 A1
(43) Pub. Date: Nov. 16, 2006

(54) Photo mask and method to form a self-assembled monolayer and an inorganic ultra thin film on the photo mask

(76) Inventors: Karin Eggers, Dresden (DE); Dieter Rutzinger, Dresden (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/128,412

(22) Filed: May 13, 2005

(51) Int. Cl. B32B 9/00; B32B 17/10; B32B 17/06; G03F 1/00

(52) U.S. Cl. 430/5; 428/428; 428/430

(57) ABSTRACT

A SAM is formed on a photo mask by providing the photo mask, preparing a solution of a reactant in a suitable solvent, and applying the solution of the reactant to the surface of the photo mask to form an organic SAM. The photo mask has a transparent substrate and a mask pattern. The reactant has an organic chain and an active head. In a further refinement, the organic SAM can be oxidized, such that an inorganic film is formed from the active head, and the organic chain is removed. The solution may be prepared, e.g., using a reactive silane head as the reactant species. The inorganic film includes SiO₂.

### BACKGROUND

The invention relates to a photo mask for transferring a mask pattern onto a substrate, and more particularly, to passivating the surface of a photo mask, and forming a self-assembled monolayer (SAM) on the photo mask.

### FIELD OF THE INVENTION

When manufacturing integrated circuits, patterns are successively transferred from photo masks reticles into photosensitive resist layers formed on substrates, e.g., semiconductor wafers, which are then post-processed in order to transfer the pattern further into an underlying layer. With the continued increase of structure densities to be accomplished on the wafer, the resolution capability requirements of the photo masks have increased. Therefore, resolution enhancement techniques such as alternating or attenuated phase shift masks, etc., are employed in semiconductor manufacturing.

However, defects occurring on a mask level may strongly affect the result on a wafer, specifically when placed in the focal plane of dense structure areas. In the case of high end mask manufacturing, there are stringent requirements that structures on a mask are manufactured dimensionally stable and that formation of contaminating particles adhering to the mask or growth of films and/or crystals, which might contribute to the imaging of the pattern onto wafer, is effectively reduced.

These requirements not only have to be maintained during mask manufacturing but also when using the photo mask during chip manufacturing, i.e., while projecting the pattern onto the wafer. For example, growth of crystals on the photo mask may be strongly enforced by the presence of high energy radiation, such as when F₂—, KrF— or ArF excimer lasers are used as illumination sources. Therein, crystal growth occurs on both the patterned and glass side of photo masks at wavelengths of 157 nm, 193 nm, or 248 nm independent of the specific dose applied.

Crystal growth on photo masks, which can be due to the exposure within exposure tools, such as steppers and scanners, may result in the formation of additional or extended features, which may lead to shorts between lines or extension of contact holes and can consequently cause line stops in production. For example, when the crystals grow to sizes sufficient to be printed on a wafer. Consequently, the yield of chip production is considerably decreased.

One cause for crystal growth is ultra thin films of ammonium sulfate, which are nearly inevitably present on the surfaces of photo masks, because in order to clean a photo mask, a solution of sulfuric acid and hydrogen peroxide, known as Piranha solution, and ammonium hydroxide is applied to the mask surface. Moieties of ammonium sulfate are always retained on the surface, which then serve as nutrients for the formation of crystals.

The crystals are formed due to diffusion processes activated by radiation in the exposure tools (5.0 eV at 248 nm, 6.4 eV at 193 nm, and 7.9 eV at 157 nm, if 157 nm technology would be reactivated). Unfortunately, no sulfate free cleaning technique has been reported. For example, in Grenon, B. J.; Bhattacharyya, K.; Volk, W.; Poock, A.; “Reticle surface contaminants and their relationship to sub-pellicle particle formation”; Proc. SPIE Vol. 5256, 2003, 1103-1110, and Grenon, B. J.; Bhattacharyya, K.; Volk, W.; Phan, K.; Poock, A.; “Reticle surface contaminants and their relationship to sub-pellicle defect formation”; Proc. SPIE Vol. 5375, 2004, 355-362, the authors conclude that the semiconductor industry will have to live with this problem for some more years until solutions can be found.

One solution might be to apply a further cleaning step in order to remove the grown crystals from the surface. However, in that case, that phase shift masks are affected by crystal growth and then cleaned, and the phase angle is disadvantageously reduced as the cleaning solution acts differently on phase shifter and quartz material. Since affected masks tend to show crystal growth again, each further cleaning step leads to an even smaller phase angle resulting in a smaller process window of the corresponding lithographic step.

In semiconductor industry, crystal growth is mainly based on ammonium sulfate. However, similar arguments as presented above may apply to crystals growing from like materials and the present invention is not limited to be applied to the problem of crystal growth purely due to ammonium sulfate.

Another possible solution can be to monitor the clean room air in regular intervals, and thereby to control and reduce the sulfur dioxide and amine/ammonia levels.

Prevention of crystal growth on photo masks, reduction of the influence of multiple cleaning steps particularly on phase shift masks, improvement of the quality of a passivation layer formed on photo mask surfaces, and reduction impact on optical properties during pattern transferal onto substrates such as wafers by exposure is desirable.

### SUMMARY

A photo mask for transferring a mask pattern onto a substrate, including a transparent substrate, and an organic SAM on the surface of the substrate. The mask pattern formed on a surface of the substrate includes light transmitting and light absorbing or attenuating portions. The film covers at least the mask pattern, and the organic SAM includes compounds with an active head and an organic chain.

A photo mask for transferring a mask pattern onto a substrate includes a transparent substrate, and an inorganic SAM on the surface of the substrate. The mask pattern formed on a surface of the substrate includes light transmitting and light absorbing or attenuating portions. The film covers at least the mask pattern and the inorganic film includes SiO₂.

A method of forming a SAM on a photo mask with a transparent substrate and a mask pattern includes providing the photo mask, preparing a solution of compounds in a suitable solvent, and applying the solution of compounds to the surface of the photo mask to form an organic SAM. Each compound has an organic chain and an active head.

Further, a method of photolithographically transferring a pattern onto a substrate, includes providing a substrate includes providing a photo mask between the layer of photoresist thereon, providing a photo mask between the layer of photoresist and a radiation source and irradiating the photo mask with light from the radiation source for imaging the mask pattern formed on the photo mask onto the substrate, and exposing the layer of photoresist with the mask pattern. The photo mask has a transparent substrate and an inorganic film applied to the surface of the substrate. The mask pattern formed on a surface of the substrate includes light transmitting and light absorbing or attenuating portions. The film covers at least the mask pattern. The inorganic film includes SiO₂.

An ultra thin inorganic layer of, e.g., SiO₂ is deposited on a surface of a photo mask. The surface that is covered by the inorganic layer relates at least to that portion of a mask, which is exposed in lithography tools and has the mask pattern. This exposed surface portion defines a front side of a mask. However, the invention includes covering only the front side with this layer or both, the front side and a back side, etc., of a photo mask.

The effect of this ultra thin layer is, that an ammonium sulfate layer, that is present on the mask due to, e.g., a previous cleaning step, is removed from the surface by capping in order to avoid further crystal growth, when the photo mask is employed to transfer a pattern onto a substrate such as a wafer.

According to the present method, a solution which is to form a SAM on a surface is applied to the mask. Therein the whole mask surface or selected portions thereof may be supplied with this layer as explained above. The reactive species for the SAM includes an organic, e.g., a long aliphatic chain and a reactive head, which, for example, is silane. The silane has been found to connect to solid materials of the mask surface, most notably oxides, but also to materials with a lower density of hydroxyl groups on that surface.

The solution thus includes at least the reactive species for the SAM, water and a solvent. The solvent may include, but is not limited to, alcohols, alkanes, aromatics, etc. The deposition of the solution may be carried out by, among others, spin coating, spray coating, meniscus coating, or dip coating processes.

A mild atomic layer deposition (ALD) technique can be performed, which involves room temperatures. Commonly, such a deposition is operated as a thermal ALD at high temperatures ranging from 180° C. (prior art ALD using HfO₂) up to 350° C., depending on the composition of the deposition material in order to activate the substrate surface. This is necessary to encourage the formation of the deposition layer. However, differing coefficients of expansion of its components with respect to glass, the attenuating material, or the absorbing material, respectively, urge towards moderate ambient temperatures for the mask in order to impede tensions across the mask surface. However, mask cleaning commonly takes place at temperatures well below 100° C.

An alternative passivation method at ambient temperatures is, for example, the sol gel process leading to thicker layers larger than 20 nm, which disadvantageously have an impact on the optical properties of a photo mask and might require sometimes a calcination step at higher temperatures.

As a result, temperatures should be kept below 100° Celsius, which in contrast to prior art is possible by the present invention. This technique may be applied even at room temperature or below, and for materials that are optically transparent at exposure wavelengths of 157 nm, 193 nm, 248 nm, etc.

As a result of the deposition step, an organic SAM is formed on the surface of the mask. Therein the active head is connected to the surface while the densely packed organic chain of each compound is directed away from the surface. Due to the alignment of their hydrophobic organic chains densely packed and highly ordered monolayers connected to the mask surface by their silane head are generated. The solvent and further compounds, that are incapable of finding a free place on the surface to adhere to are finally removed by a solvent dispense and spinned off. Consequently, the formation of a monolayer involves only one layer of single compounds of the solution, which adhere to the mask surface.

A further aspect of the invention relates to performing an oxidation of the deposited material. For this purpose, the mask is provided to a UV/ozone chamber. Therein, ozone is in situ generated and then decomposed to form an oxygen radical. This radical then acts as an oxidizing agent for the organic part of the SAM.

In one aspect, the active head is a reactive silane head. As a result of oxidation, a monolayer of SiO₂ is provided on the surface of the mask. SiO₂ offers sufficient optical properties, especially in the case of an ultra thin thickness, such that an optical impact on the image transfer onto wafers is likewise negligible.

During the oxidation step the organic chain is removed and the organosilane layer is thereby transformed into a hydrocarbon free and pure inorganic SiO₂ layer. Due to the absence of hydrocarbons, the inorganic film influences the optical properties of the photo mask less than other known, commonly thicker, layers.

As a result an organic SAM according to this embodiment is, for passivation purposes of the mask surface against crystal formation, transformed into an ultra thin (2.75 Angstrom) inorganic SiO₂ layer, which is resistant against 193 nm and 248 nm exposure light. This inorganic SiO₂ monolayer provides more mechanical stability for rework and passivates the mask surface.

The transfer of the organic film into the inorganic layer is necessary since the organic compound is unstable against the scanner exposure light (i.e., 5.0 eV at 248 nm, 6.4 eV at 193 nm). For example, bond energies of organic materials are, e.g., C—C, 3.6 eV or C—H, 4.3 eV. Exposing an organic layer at the given wavelengths would lead to organic contamination of the mask.

According to this embodiment that relates to providing silane as a compound, a further refinement can be made by applying several cycles of the monolayer formation to the mask surface. One cycle leads to a SiO₂ monolayer having a thickness 2.75 Angstrom. Repeating this cycle n times then results in a stack of layers which have a thickness of n*2.75 Angstrom due to uniform growth.

It has been found that film growth continues for more than 20 cycles to stay uniform in thickness across the mask surface (Vallant, T. et al; Monolayer-controlled deposition of silicon oxide films on gold, silicon and mica substrates by room-temperature adsorption and oxidation of alkylsiloxane monolayers; J. Phys. Chem. B, 2000, 104, 5309-5317). As a result, the formation of a passivation layer against crystal growth may be controlled accurately to within a scale of single angstroms. The thickness of the monolayer film including several monolayers may be chosen according to the optical requirements specified for the mask which is to be passivated.

The passivation layer can be applied to chrome on glass masks (CoG), chromeless phase shift layer masks (CPL) and phase shift masks (PSM). In an embodiment wherein the method is applied to PSM, particularly, halftone PSM having an attenuating layer of, e.g., MoSiON, the problems of tension due to different thermal expansion of the materials involved are relaxed since the temperatures chosen for the deposition are moderate as explained above.

Further, less cleaning steps are necessary due to the invention as crystal growth is impeded. Consequently, phase angles between phase shifting portions and non-phase shifting portions (alternating phase shift masks (altPSM) as well as halftone phase shift masks (HTPSM), etc.) are relatively constant during the lifetime of the masks. In particular, a SiO₂ monolayer or film having a number of monolayers may protect an underlying MoSi-phase shifting layer (HTPSM), or the quartz substrate in the case of an altPSM.

Although the embodiments of the present invention have been described in detail, the invention may be embodied in other specific forms without departing from the spirit or essential characteristics thereof. The present embodiments are therefore to be considered as illustrative and not restrictive, the scope of the invention being indicated by the appended claims rather than by the foregoing description and all changes which come within the meaning and range of equivalency of the claims are therefore intended to be embraced therein.

The invention will become more clear with respect to embodiments when taken in conjunction with the accompanying drawings.

### BRIEF DESCRIPTION OF THE DRAWINGS

FIGS. 1-3 show a first embodiment according to the present invention wherein a film comprising a SiO₂ monolayer is formed on the mask surface;

FIG. 4 shows a second embodiment according to the present invention with repeated formation of an inorganic film on the mask surface;

FIG. 5 shows a diagram of evolution of thickness d with respect to cycle number according to the second embodiment of the invention, wherein an inorganic film is repeatedly formed on a mask surface; and

FIG. 6 shows a flow chart of the first embodiment of method according to the invention.

### DETAILED DESCRIPTION OF THE EMBODIMENTS

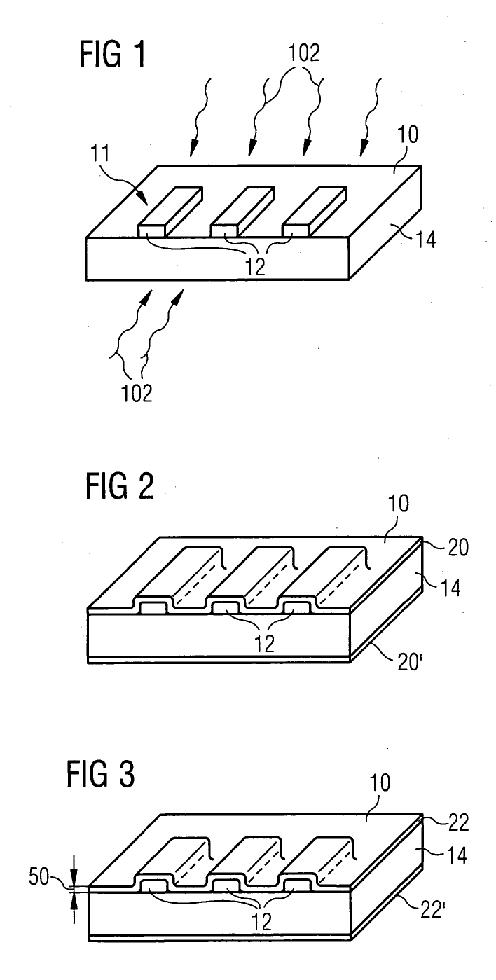

A first embodiment of a method according invention is shown in FIGS. 1-3. This embodiment relates to forming an organic self-assembled monolayer (SAM) first and then oxidizing the SAM in order to yield an inorganic passivating film. This embodiment accordingly relates to a two step procedure.

The formation of the inorganic film is carried out using octadecylsilane compounds as a silane source. Experiments show that a C₁₈ chain is necessary to obtain densely packed and highly ordered monolayers. Both trichloro- and alkoxysilanes can be used. Trichlorosilanes are preferred since hydrolysis and deposition occur faster.

At first, a solution is prepared (reference sign 104) from octadecylsilane compounds dissolved in aromatic, long-chain aliphatic or alcoholic solvents such as benzene, toluene, octadecane, hexadecane, dodecane, isopropanole etc. The silane concentration is varied between 0.5-50 mmol, e.g., 20 mmol per liter. The water content within the solvent ranges between 1 and 50 mmol per liter, e.g., 25 mmol per liter. The parameters as provided here lead to the formation of a particularly high-quality SAM in a time scale between some seconds and one hour.

The solution is applied as prepared to the surface of a photo mask as shown in FIG. 1, e.g., a spin coating process 106 is used. FIG. 1 illustrates a portion of a halftone phase shift mask 10 comprising a transparent quartz substrate 14 and line structure elements 12 formed from a phase-shifting and light attenuating material, which has previously been deposited and structured on the mask surface 10 to form a mask pattern 11. After that pattern forming process, a mask cleaning step 102 in order to remove contaminating particles may have been applied. After spinning of the cleaning solution, residues may have survived on the mask surface.

The solution is applied to a front side surface comprising the mask pattern 11 as well as to a back side surface of the photo mask 10, which is defined by the plane substrate. The solution is intended to impede crystal growth, which otherwise starts from the remaining ammonium sulfate nutrients.

FIG. 2 shows the photo mask 10, which is now covered with an organic self-assembled monolayer 20. This layer 20 has a thickness d of about 26 Angstrom as shown in the diagram FIG. 5, where thickness d is plotted versus cycle number n, wherein currently n equals 1. The photo mask 10 is further provided into an UV/ozone-chamber (step 108) to oxidize the organic chain. The UV/ozone-chamber is operated at wavelengths of 185 nm to form ozone from molecular oxygen and 250 nm to decompose this ozone to liberate an oxygen radical which acts as the oxidizing agent (mercury lamp, or alternatively, a 172 nm excimer lamp can be used). The oxidation step 108 leads to a SiO₂ monolayer with a reduced thickness of 2.75 Angstrom, which is free of hydrocarbon and provides sufficient optical properties for exposure applications at wavelengths of 193 nm and 248 nm.

This oxidation step 108 involves a transformation of the organic SAM 20 into a pure SiO₂ film 22 as shown in FIG. 3. Coincidently, an organic SAM layer 20′ on the backside surface of the photo mask 10 is transformed into an inorganic SiO₂ monolayer 22′.

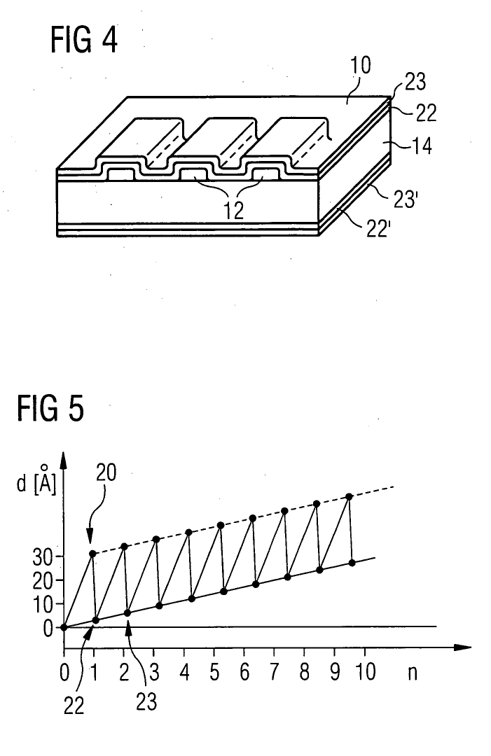

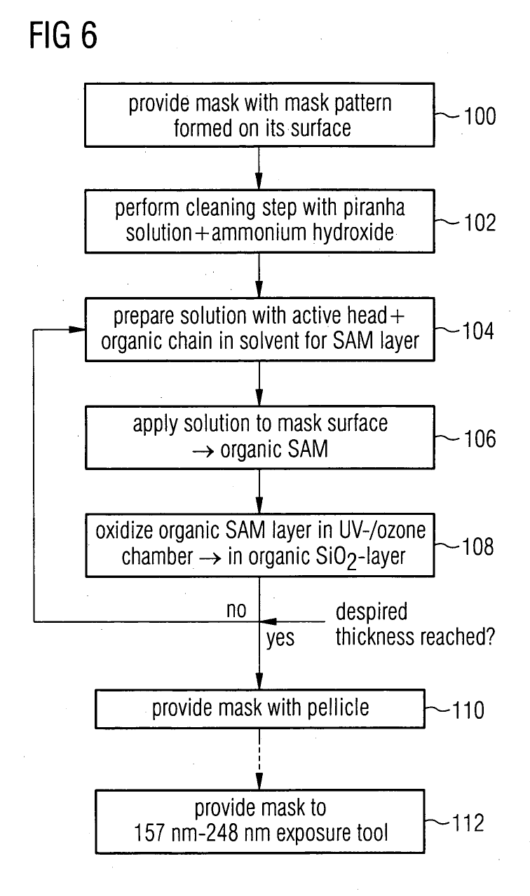

As is illustrated in FIG. 6, it is possible to apply a number of further monolayers 23 to the mask surface. In this case, steps 104, 105, 106 can be repeated for n cycles. The application of one further SiO₂ monolayer 23, 23′ is also indicated in FIG. 4. During this repeated two step procedure (steps 106, 108 disregarding the prepare step for the moment) the underlying first SiO₂ monolayer 22, 22′ is not dissolved. Accordingly, a multilayer film results from such a repeated deposition.

When the desired thickness has been reached, the repetition of adsorption and oxidation cycles is stopped and a pellicle (not shown) along with its frame may be mounted to the photo mask 10 (step 110).

Further, in the progress of employing the photo mask 10 for transferring the pattern 11 onto a substrate such as a wafer, the mask 10 is provided to an exposure tool having an exposure light beam operated at a specific wavelength. Usually, the mask pattern 11 and the photo mask 10 are adapted to be exposed at one of these specific wavelengths such as 157 nm, 193 nm or 248 nm (optional step 112).

The inorganic SiO₂ film is notably resistant against 248 nm and 193 nm exposure light and further provides improved mechanical stability. On the contrary, an unmodified SAM with an organic chain (i.e., having performed only the first step) would be unstable against the exposure light in a scanner. This again would inadvertently lead to organic contamination on the mask surface in particular within the pellicle protected area. Gaseous, organic fragments inside the space beneath the pellicle membrane, the pellicle frame and the mask substrate can not be easily transported away.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCE NUMERALS

10 photo mask having a surface
11 mask pattern
12 structure elements
14 substrate
20 organic SAM
22 inorganic SiO₂ monolayer
23 further inorganic SiO₂ monolayer
50 thickness, also denoted as “d”
100 providing a mask
102 mask cleaning
104 preparing of solution
106 spin coating
108 oxidation
110 pellicle mounting
112 transferal of mask to exposure tool

What is claimed is:

1. A photo mask for transferring a mask pattern onto a substrate, comprising:
a transparent substrate;
the mask pattern, the mask pattern being formed on a surface of the substrate, the mask pattern including light transmitting and light absorbing or attenuating portions; and
an organic SAM, the organic SAM disposed on the surface of the substrate and covering at least the mask pattern, the organic SAM including compounds having an active head and an organic chain.

2. The photo mask according to claim 1, wherein the compounds each include a reactive silane head.

3. The photo mask according to claim 1, wherein the compounds each include an aliphatic chain.

4. The photo mask according to claim 3, wherein the aliphatic chain of the compound includes more than 8 and less than 25 C-atoms.

5. The photo mask according to claim 1, wherein the transparent substrate comprises glass or quartz.

6. The photo mask according to claim 5, wherein the mask pattern and/or the transparent substrate comprise portions, which are arranged to phase-shift incident light with respect to each other.

7. The photo mask according to claim 6, wherein the mask pattern, which is covered by the organic SAM, including phase-shifting portions, the phase-shifting portions being provided by a layer comprising molybdene silicide or silicon dioxide.

8. The photo mask according to claim 1, wherein the organic SAM is substantially transparent to incident light within an ultraviolet wavelength range.

9. The photo mask according to claim 1, wherein the organic SAM has a thickness in the range between 10 Angstrom and 50 Angstrom.

10. A photo mask for transferring a mask pattern onto a substrate, comprising:
a transparent substrate;
the mask pattern, the mask pattern being formed on a surface of the substrate, the mask pattern including light transmitting and light absorbing or attenuating portions; and
an inorganic film on the surface of the substrate covering at least the mask pattern, the inorganic film including SiO₂.

11. The photo mask according to claim 10, wherein the transparent substrate comprises glass or quartz.

12. The photo mask according to claim 11, wherein the mask pattern and/or the transparent substrate each include a plurality of portions, the portions being arranged to phase-shift incident light with respect to each other.

13. The photo mask according to claim 12, wherein the mask pattern, which is covered by the inorganic film, includes phase-shifting portions, the phase-shifting portions being provided by a layer including molybdene silicide or silicon dioxide.

14. The photo mask according to claim 10, wherein the inorganic film is substantially transparent to incident light within an ultraviolet wavelength range.

15. The photo mask according to claim 10, wherein the inorganic film has a thickness in the range of approximately 2 Angstrom and 75 Angstrom.

16. The photo mask according to claim 10, wherein the inorganic film includes a multiple of single monolayers deposited one above the other on the mask surface.

17. The photo mask according to claim 16, wherein at least one and up to 20 monolayers are deposited on the mask surface.

18. The photo mask according to claim 10, wherein the inorganic film includes one monolayer with a thickness in the range between 2 Angstrom and 50 Angstrom.

19. The photo mask according to claim 18, wherein the monolayer is less than 1 nm.

20. A method of forming a SAM on a photo mask with a transparent substrate and a mask pattern, comprising:
providing the photo mask;
preparing a solution of a reactant in a suitable solvent, the reactant having an organic chain and an active head; and
applying the solution of the reactant to the surface of the photo mask to form an organic SAM.

21. The method according to claim 20, further comprising:
oxidizing the organic SAM, such that an inorganic film is formed from the active head and the organic chain is removed.

22. The method according to claim 20, wherein the solution is prepared using the reactant having a reactive silane head.

23. The method according to claim 20, wherein oxidizing the organic SAM is performed such that the inorganic film, which is formed from the reactive silane head includes SiO₂.

24. The method according to claim 20, wherein oxidizing the organic SAM is performed by providing the photo mask to a UV/ozone-chamber in order to expose the organic SAM to ozone generated within the UV/ozone-chamber.

25. The method according to claim 24, wherein oxidizing within the Uv/ozone-chamber is first operated at wavelengths of about 185 nm and 254 nm using a mercury lamp or 172 nm using a Xe2 excimer lamp.

26. The method according to claim 20, wherein applying the solution to the surface of the photo mask includes depositing the solution within a temperature range between 15° Celsius through 50° Celsius.

27. The method according to claim 20, wherein the solution is prepared using the reactant having an aliphatic chain.

28. The method according to claim 27, wherein the aliphatic chain includes at least 8 and less than 25 C-atoms.

29. The method according to claim 28, wherein the aliphatic chain includes 18 C-atoms.

30. The method according to claim 20, wherein the solution is prepared with a silane content in the range between approximately 0.1 mmol per liter and 50 mmol per liter.

31. The method according to claim 20, wherein the solution is prepared with a silane content in the range between approximately 0.5, mmol per liter and 25 mmol per liter.

32. The method according to claim 20, wherein the solution is prepared with a solvent, which is at least one of a group comprising: isopropyl alcohol (isopropanole), benzene, toluene, octadecane, hexadecane, or dodecane.

33. The method according to claim 20, wherein the solution is prepared with a solvent, which is at least one of a group comprising: alcohols, aromatics, or alkanes.

34. The method according to claim 20, wherein the solution is prepared with a solvent, which includes a water content of 250 mmol per liter or less.

35. The method according to claim 20, wherein the solution is prepared with a solvent, that has a ratio of silane to water in the range between 1:1 and 1:30.

36. The method of claim 20, wherein applying the solution to the surface of the photo mask includes one of a group comprising: spin coating, spray coating, meniscus coating, or dip coating.

37. A method of photolithographically transferring a pattern onto a substrate, comprising:
providing a substrate having a layer of photoresist thereon;
providing a photo mask between the layer of photoresist and a radiation source, the photo mask including:
(a) a transparent substrate,
(b) the mask pattern, which is formed on a surface of the substrate, the mask pattern having light transmitting and light absorbing or attenuating portions, and
(c) an inorganic film applied to the surface of the substrate, the film covering at least the mask pattern, wherein the inorganic film includes SiO₂; and
irradiating the photo mask with light from the radiation source for imaging the mask pattern formed on the photo mask onto the substrate, thereby exposing the layer of photoresist with the mask pattern.

38. The method according to claim 37, wherein the radiation has a wavelength of one of 365 nm, 248 nm, 193 nm, or 157 nm.

39. The method according to claim 37, wherein the radiation has a wavelength of 13.4 nm.

40. The method according to claim 37, wherein the photo mask further includes a pellicle, the pellicle having a pellicle frame and a pellicle membrane mounted thereon, the pellicle disposed on the surface of the substrate so that the inorganic film is interposed between the mask pattern and the pellicle membrane, such that radiation from the radiation source passes through the photo mask before passing through the pellicle membrane.

41. The method according to claim 37, wherein the photo mask further includes a pellicle, the pellicle having a pellicle frame and a pellicle membrane mounted thereon, the pellicle disposed on the surface of the substrate so that the inorganic film is interposed between the mask pattern and the pellicle membrane, such that radiation from the radiation source passes through the pellicle membrane before passing through the photo mask.
